(19) United States
(12) Patent Application Publication
(10) Pub. No.: US 2018/0348277 A1
(43) Pub. Date: Dec. 6, 2018

(54) Circuit Apparatus, Physical Quantity Measuring Apparatus, Electronic Device, And Vehicle

(71) Applicant: Seiko Epson Corporation, Tokyo (JP)

(72) Inventor: Hideo HANEDA, Matsumoto (JP)

(21) Appl. No.: 15/986,005

(22) Filed: May 22, 2018

(30) Foreign Application Priority Data
May 31, 2017 (JP) 2017-107468

(51) Int. Cl. G01R 29/26; G01R 23/165; G01D 3/08; G01C 19/5614; G01C 19/5621; B60R 16/023

(52) U.S. Cl. CPC G01R 29/26; G01R 23/165; B60R 16/0232; G01C 19/5614; G01C 19/5621; G01D 3/08

(57) ABSTRACT

A circuit apparatus is a circuit apparatus used for a physical quantity measuring apparatus, including a detection circuit that performs physical quantity detection processing based on a detection signal from a physical quantity transducer and a processing circuit that performs processing based on an output signal of the detection circuit. The processing circuit obtains index information of floor noise generated in the detection circuit based on the output signal and performs abnormality detection of the physical quantity measuring apparatus based on the index information.

### BACKGROUND

### 1. Technical Field

The present invention relates to a circuit apparatus, a physical quantity measuring apparatus, an electronic device, a vehicle, and the like.

### 2. Related Art

In electronic devices such as digital cameras and smartphones, and vehicles such as cars and airplanes, a physical quantity measuring apparatus for detecting physical quantities which change due to external factors is incorporated. For example, a gyro sensor that detects an angular velocity is used for so-called camera shake correction, attitude control, GPS autonomous navigation, and the like.

In order to properly perform processing such as camera shake correction, attitude control, and the like, it is important to detect an abnormality of the physical quantity measuring apparatus. In a case where an abnormality occurs in the physical quantity measuring apparatus, the physical quantity to be measured deviates from an original value (an original angular velocity if the physical quantity measuring apparatus is a gyro sensor), and appropriate processing may not be executed.

For example, JP-A-2010-107416 discloses a method for tuning a self-vibration component to shift from zero and determining a failure when the extracted self-vibration component decreases in the tuning of a vibrator (physical quantity transducer).

In addition, JP-A-2015-114220 discloses a method for reducing a DC offset (error of a zero point) in a gyro sensor by using the Kalman filter that extracts the DC component of an input signal. Detection errors of angles may be reduced, and processing such as camera shake correction may be performed with high accuracy by reducing the DC offset.

In a physical quantity measuring apparatus, a connection abnormality between a physical quantity transducer and a detection circuit may occur. For example, in a gyro sensor, a failure mode in which at least one of a sensor detection electrode and a pad of the detection circuit is disconnected is conceivable. In this failure mode, a sensor signal (detection signal) may not be detected at all, but causes only a phenomenon such as a sensitivity abnormality and zero point variation. For example, in a case where the angular velocity detected by the gyro sensor decreases, it is not easy to determine whether the rotation is actually small (slow) or whether the gyro sensor is in the failure mode.

In the method of JP-A-2010-107416, in order to detect the failure mode (connection abnormality), it is necessary to set and detect a self-vibration component (leakage vibration component), and in addition to a physical quantity detection circuit, a self-vibration component extraction circuit including a synchronous detection circuit, an amplifier, an integration circuit, and the like is provided. Therefore, even in a case where a detection element and the physical quantity detection circuit have no problem, but in a case where an abnormality occurs in this self-vibration component extraction circuit, there is a problem that it is determined as a failure. In addition, the method of JP-A-2015-114220 is intended to improve the detection accuracy of the gyro sensor and does not perform abnormality detection.

### SUMMARY

An advantage of some aspects of the invention is to solve at least a part of the problems described above, and the invention can be implemented as the following forms or embodiments.

An aspect of the invention relates to a circuit apparatus used in a physical quantity measuring apparatus, the apparatus including a detection circuit that performs physical quantity detection processing based on a detection signal from a physical quantity transducer and a processing circuit that performs processing based on an output signal of the detection circuit, in which the processing circuit obtains index information of floor noise generated in the detection circuit based on the output signal and performs abnormality detection of the physical quantity measuring apparatus based on the index information.

In the aspect of the invention, the processing circuit may detect abnormality of the physical quantity measuring apparatus based on index information of the floor noise generated in the detection circuit. With this configuration, it is possible to appropriately detect a connection abnormality which is an abnormality in a signal processing path from the physical quantity transducer to the detection circuit and is not easy to detect by signal level determination of the detection signal or the like.

In the aspect of the invention, the processing circuit may perform the abnormality detection of the connection between the physical quantity transducer and the detection circuit based on the index information.

With this configuration, it is possible to appropriately detect a connection abnormality between the physical quantity transducer and the detection circuit.

In the aspect of the invention, the processing circuit may include an abnormality detection unit that compares an index value that is the index information of the floor noise with a threshold value and performs the abnormality detection.

With this configuration, it is possible to detect an abnormality by threshold determination using the index value of the floor noise.

In the aspect of the invention, the detection circuit may include an amplifier circuit to which the detection signal is input and the floor noise includes floor noise generated in the amplifier circuit.

With this configuration, it is possible to perform abnormality detection or the like based on the index information of the floor noise generated in the amplifier circuit.

In the aspect of the invention, the amplifier circuit may be a Q/V conversion circuit or an I/V conversion circuit.

With this configuration, in the case of using the Q/V conversion circuit or the I/V conversion circuit as the amplifier circuit, it is possible to appropriately perform abnormality detection or the like.

In the aspect of the invention, the processing circuit may include a floor noise detection circuit that detects the index information of the floor noise, and the floor noise detection circuit includes an arithmetic circuit that obtains an effective value of the floor noise.

With this configuration, it is possible to obtain an effective value of the floor noise as the index information of the floor noise.

In the aspect of the invention, the floor noise detection circuit may include a high-pass filter that performs filter processing on the output signal of the detection circuit and the arithmetic circuit, in which the arithmetic circuit may include a square arithmetic processing unit that performs a square operation on the filtered signal or an absolute value arithmetic processing unit that performs absolute value operation on the filtered signal, and a smoothing circuit that smoothes the output of the square arithmetic processing unit or the absolute value arithmetic processing unit.

With this configuration, it is possible to realize the floor noise detection circuit with an appropriate configuration.

In the aspect of the invention, the processing circuit may include the Kalman filter for performing Kalman filter processing based on an observation noise and a system noise to extract a DC component of the output signal of the detection circuit, and the index information of the floor noise may be error covariance output from the Kalman filter.

With this configuration, it is possible to obtain the index value of the floor noise by using the Kalman filter that extracts the DC component of the output signal.

In the aspect of the invention, the processing circuit may include the Kalman filter for performing Kalman filter processing based on the observation noise and the system noise to extract a DC component of the output signal of the detection circuit and a noise estimation unit that obtains the index information based on the output signal of the detection circuit, in which the noise estimation unit may estimate the observation noise and the system noise based on the index information and outputs the observation noise and the system noise to the Kalman filter.

With this configuration, it is possible to obtain the index value of the floor noise by using a noise estimation unit for dynamically changing the observation noise and the system noise used in the Kalman filter.

Another aspect of the invention relates to a physical quantity measuring apparatus including the circuit apparatus as described above and the physical quantity transducer.

Another aspect of the invention relates to an electronic device including any of the circuit apparatuses described above.

Another aspect of the invention relates to a vehicle including any of the circuit apparatuses described above.

### BRIEF DESCRIPTION OF THE DRAWINGS

The invention will be described with reference to the accompanying drawings, wherein like numbers reference like elements.

FIG. 1 is a configuration example of a circuit apparatus.

FIG. 2 is a configuration example of an amplifier circuit.

FIG. 3 is an explanatory diagram of floor noise of the amplifier circuit.

FIG. 4 is an example of a characteristic of a noise gain (noise transfer function).

FIG. 5 is an example of the characteristic of the noise gain (noise transfer function).

FIG. 6 is a waveform diagram showing a temporal change in a detection signal and a floor noise effective value.

FIG. 7 is another configuration example of the amplifier circuit.

FIG. 8 is a configuration example of a processing apparatus according to a first embodiment.

FIG. 9 is a configuration example of a processing apparatus according to a second embodiment.

FIG. 10 is a timing chart schematically showing an operation of the processing apparatus.

FIG. 11 is a configuration example of a processing apparatus according to a third embodiment.

FIG. 12 is a detailed configuration example of a processing apparatus.

FIG. 13 is a diagram for explaining a threshold value setting method.

FIG. 14 is a detailed configuration example of the circuit apparatus.

FIG. 15 is a configuration example of a physical quantity measuring apparatus.

FIG. 16 is a configuration example of an electronic device.

FIG. 17 is a configuration example of a vehicle.

### DESCRIPTION OF EXEMPLARY EMBODIMENTS

Hereinafter, a preferred embodiment of the invention will be described in detail. The present embodiment described below does not unduly limit the contents of the invention described in the appended claims, and not all of the configurations described in the embodiment are necessarily indispensable as a solving means of the invention.

### 1. Method of the Embodiment

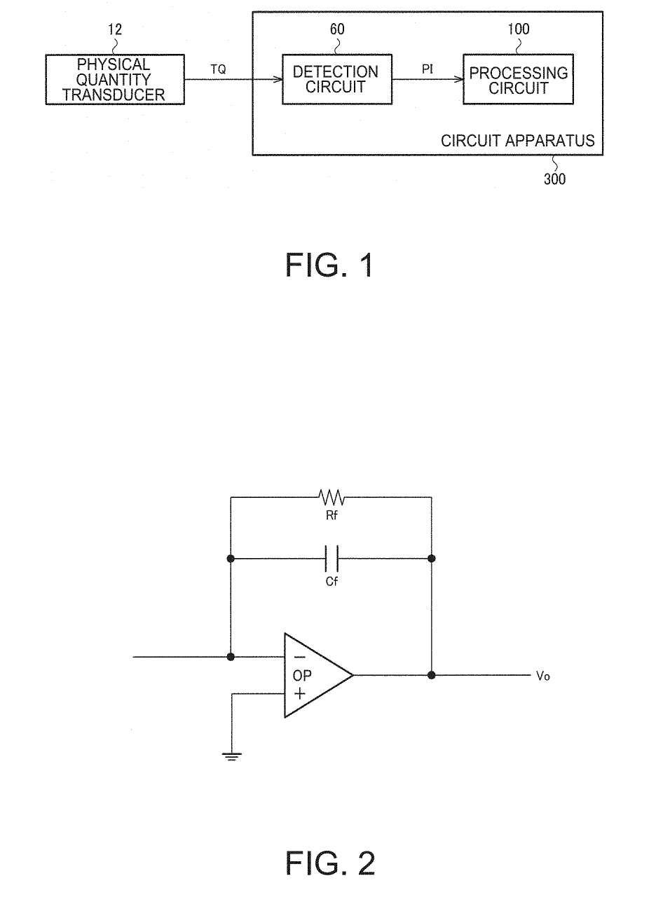

FIG. 1 shows a configuration example of a circuit apparatus 300 (integrated circuit apparatus and detection apparatus) according to the embodiment. As shown in FIG. 1, the circuit apparatus 300 of the embodiment is a circuit apparatus used for a physical quantity measuring apparatus, including a detection circuit 60 that performs physical quantity detection processing based on a detection signal TQ from a physical quantity transducer 12 and a processing circuit 100 that performs processing based on an output signal (input signal PI of a processing apparatus 100) of the detection circuit 60.

As described above, it is considered that an abnormality of the physical quantity measuring apparatus may be an abnormality in which the sensitivity or zero point of the detection signal TQ is in a state different from a normal state and does not reach a state in which the detection signal TQ may not be detected. In that case, even if the value (for example, amplitude level) of the input signal PI is simply monitored, it is difficult to detect an abnormality. This is because, when the input signal PI reaches a predetermined signal level, it may not be determined whether there is such input (for example, if there is rotation of the angular velocity corresponding to the signal level in the gyro sensor) or an abnormality.

Therefore, in the embodiment, the processing circuit 100 obtains index information of the floor noise generated in the detection circuit 60 based on the output signal of the detection circuit 60 and performs abnormality detection of the physical quantity measuring apparatus based on the index information.

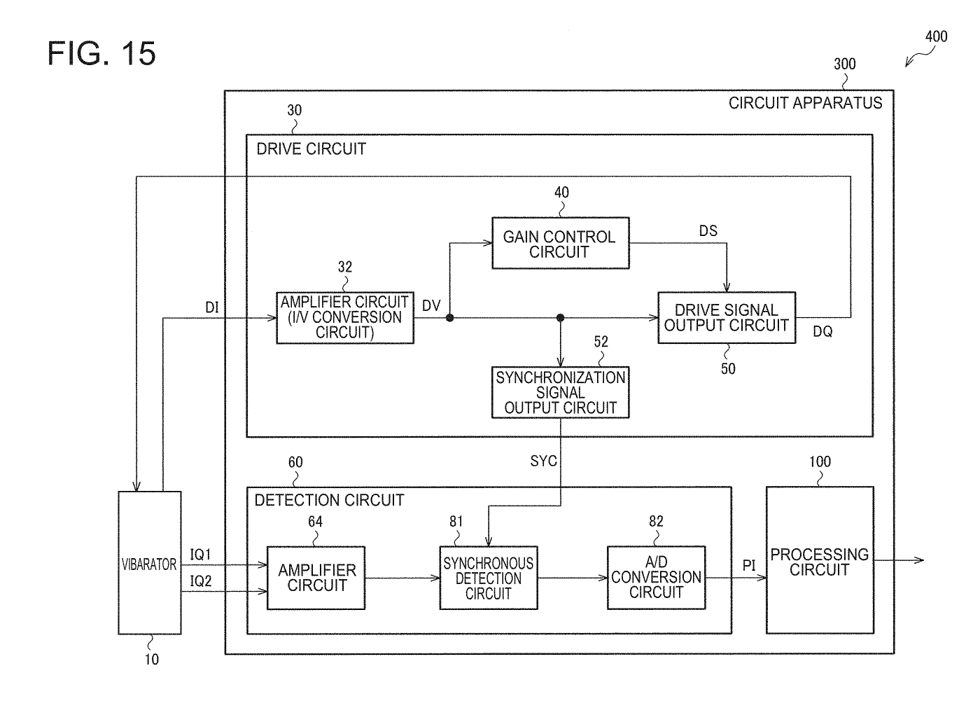

Here, the floor noise represents noise generated in the detection circuit 60, such as thermal noise or a l/f noise. Specifically, as shown in FIG. 15, the detection circuit 60 may include an amplifier circuit 64 to which the detection signal TQ (differential signals IQ1 and IQ2 in the example of FIG. 15) is input, and the floor noise may include the floor noise generated in the amplifier circuit 64. The floor noise has a certain level (amplitude) although there is a possibility that the floor noise fluctuates depending on the design of the circuit, the temperature at the time of use, the frequency of the signal, and the like. The reason why abnormality detection is possible based on the floor noise will be described below.

FIG. 2 is a configuration example of the amplifier circuit 64. The amplifier circuit 64 includes an operational amplifier OP, a resistor R_{f}, and a capacitor C_{f}. The detection signal TQ from the physical quantity transducer 12 is input to an inverting input terminal of the operational amplifier OP. A low potential side power supply (ground in a narrow sense) is supplied to the non-inverting input terminal. In addition, the resistor R_{f} and the capacitor C_{f} are provided in parallel between an output terminal and the inverting input terminal of the operational amplifier OP. That is, the resistor R_{f} and the capacitor C_{f} are a feedback resistor and a feedback capacitor.

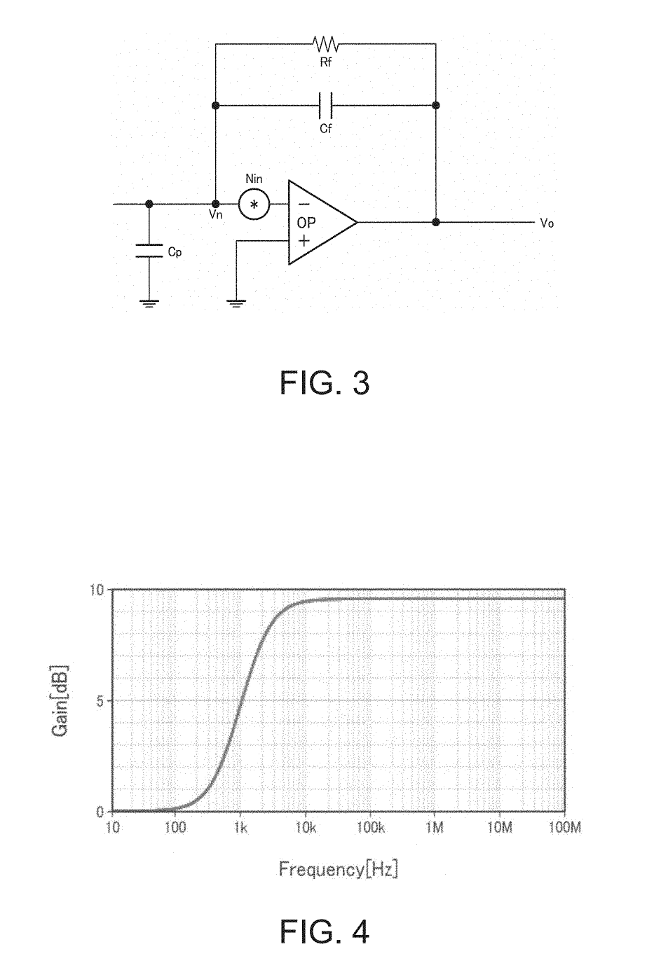

FIG. 3 shows a configuration example of the amplifier circuit 64 in a state where the detection circuit 60 and the physical quantity transducer 12 are connected. In a state where the physical quantity transducer 12 is connected, it seems that a parasitic capacitance Cₚ by the physical quantity transducer 12 is connected from an input side of the amplifier circuit 64. Specifically, as shown in FIG. 3, a state in which the parasitic capacitance Cₚ is connected between the input of the amplifier circuit 64 and a low potential side power supply (ground) may be considered.

In the amplifier circuit 64, it is assumed that the noise in the entire circuit is generated at an input point (Nin in FIG. 3) and a mode in which the input-converted noise is amplified by a noise transfer function NTF (noise gain) is widely used. In the example of FIG. 3, the noise transfer function NTF is expressed by the following Equation (1).

$$NTF = \frac{{V}_{o}}{{V}_{n}} = \frac{1 + s {R}_{f} ( {C}_{f} + {C}_{p} )}{1 + s {R}_{f} {C}_{f}} \qquad ( 1 )$$

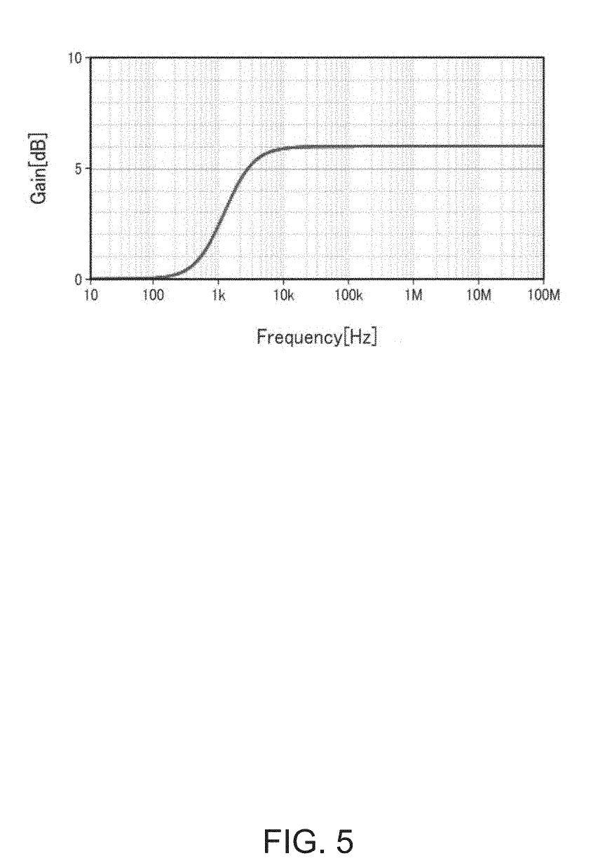

FIGS. 4 and 5 are diagrams showing frequency characteristics of the noise transfer function NTF shown in the above Equation (1). In FIGS. 4 and 5, the horizontal axis represents a frequency and the vertical axis represents a gain (amplification factor, unit dB). FIG. 4 shows an example of R_{f}=100 MΩ, C_{f}=1 pF, and Cₚ=2 pF. In addition, FIG. 5 shows an example of R_{f}=100 MΩ, C_{f}=1 pF, and Cₚ=1 pF.

As can be seen from FIGS. 4 and 5, even if the values of R_{f} and C_{f} are common (even for the same amplifier circuit 64), if the value of the parasitic capacitance Cₚ changes, the noise transfer function NTF changes. In other words, even if the level of the input-converted noise of the amplifier circuit 64 is about the same level, if the value of the parasitic capacitance Cₚ changes, the floor noise (the floor noise of the detection circuit 60) of the amplifier circuit 64 changes.

Here, if the physical quantity transducer 12 and the detection circuit 60 are normally connected, the value of the parasitic capacitance Cₚ seen from the detection circuit 60 does not change greatly and is considered to be sufficiently close to a predetermined value determined by the design. On the other hand, in a case where a connection abnormality occurs, such as disconnection of a connection signal line between the physical quantity transducer 12 and the detection circuit 60 (circuit apparatus 300), the value of the parasitic capacitance Cₚ decreases (in a narrow sense, the parasitic capacitance Cₚ due to the physical quantity transducer 12 becomes invisible from the detection circuit 60). In a case where the sensor detection electrode and the pad of the detection circuit are electrically connected by, for example, wire bonding, a connection abnormality is caused by narrowing at least one of a bonding area between the detection electrode and a wire and a bonding area between the pad and the wire (the wire peels off).

Originally, floor noise is generated at a certain level and is not supposed to be smaller than this level. However, when an abnormality occurs, the level of the floor noise decreases to such a level that the level of the floor noise may be distinguished compared to the level of the floor noise level in the normal state due to the decrease in the parasitic capacitance Cₚ. Therefore, the circuit apparatus 300 (processing circuit 100) of the embodiment obtains the index value of the floor noise and uses the index value to determine the level of the floor noise. In a case where the level of the floor noise is smaller compared to the normal state, the processing circuit 100 determines that an abnormality has occurred.

As described above, the processing circuit 100 of the embodiment performs abnormality detection of the connection between the physical quantity transducer 12 and the detection circuit 60 based on index information of the floor noise. It is possible to appropriately detect even a connection abnormality by using the index information of the floor noise, which is difficult to detect by a method simply using the signal level of the input signal PI.

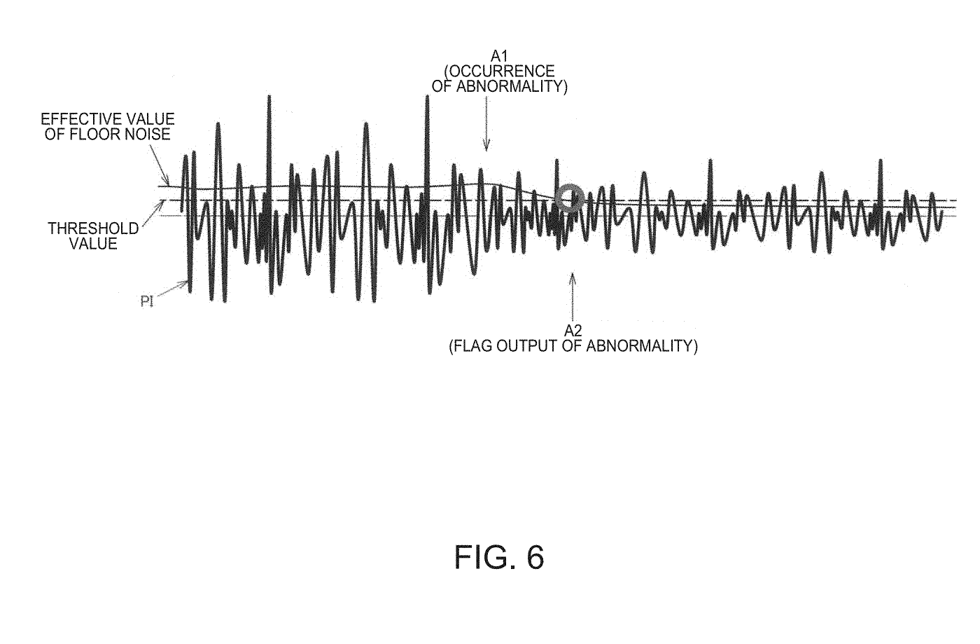

FIG. 6 is a waveform diagram showing a temporal change in the input signal PI and the index information (effective value) of the floor noise. In FIG. 6, the horizontal axis represents time and the vertical axis represents a signal value. In the example of FIG. 6, a connection abnormality occurs between the physical quantity transducer 12 and the detection circuit 60 at the timing indicated by A1.

As described above, the zero point and the sensitivity of the input signal PI of the detection circuit 60 change due to the occurrence of a connection abnormality, but the signal value itself may not become 0 in some cases. In FIG. 6, even in the period after the timing of A1, a signal other than 0 is detected as the input signal PI, and it is difficult to detect a connection abnormality by simply monitoring the input signal PI.

On the other hand, although the index information (effective value) of the floor noise maintains a value near a certain level before the timing of A1, the value clearly decreases due to the occurrence of a connection abnormality. Therefore, as shown in FIG. 6, a value between the effective value of the floor noise in the normal state (before A1) and the effective value of the floor noise at the time of the connection abnormality (after A1, in particular, a period after the effective value of the floor noise is stabilized) is set as the threshold value. Then, the processing circuit 100 detects a connection abnormality by comparing the index information (effective value) of the floor noise with the threshold value. In the example of FIG. 6, the processing circuit 100 outputs information (for example, abnormality flag) indicating a connection abnormality at the timing of A2.

In addition, the configuration of the amplifier circuit 64 of the embodiment is not limited to FIG. 2. The amplifier circuit 64 according to the embodiment is widely applicable to an amplifier circuit having a configuration in which a noise gain changes in accordance with the parasitic capacitance Cₚ.

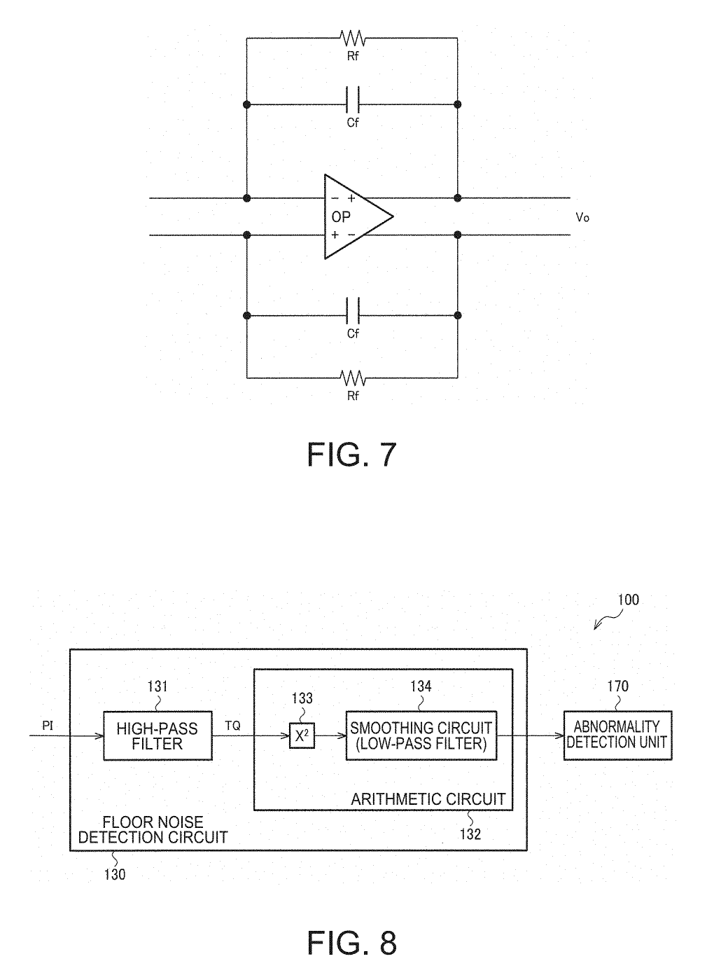

FIG. 7 is another configuration example of the amplifier circuit 64. As shown in FIG. 7, the amplifier circuit 64 may be an amplifier circuit of a differential input (and a differential output). In a broader sense, the amplifier circuit 64 of the embodiment is a Q/V conversion circuit (charge-voltage conversion circuit) or an I/V conversion circuit (current-voltage conversion circuit).

### 2. Calculation Method of Index Information of Floor Noise

In the processing circuit 100, there are several methods for obtaining index information of the floor noise of the detection circuit 60 (estimating floor noise). Hereinafter, first to third embodiments will be described.

### 2.1 First Embodiment

FIG. 8 shows a configuration example of the processing circuit 100 according to a first embodiment. As shown in FIG. 8, the processing circuit 100 includes an arithmetic circuit 132 for finding an effective value of the floor noise and a floor noise detection circuit 130 for detecting index information of the floor noise. The effective value here may be a widely-used root mean square (RMS), but is not limited thereto and may be other information corresponding to the RMS. The embodiment is not limited to the configuration of FIG. 8, and various modifications such as omitting a part of the constituent elements thereof, adding other constituent elements, and the like may be made.

As shown in FIG. 8, the floor noise detection circuit 130 may include a high-pass filter 131 and an arithmetic circuit 132. Then, the arithmetic circuit 132 includes a square arithmetic processing unit 133 and a smoothing circuit 134 that smoothes the output of the square arithmetic processing unit 133.

The high-pass filter 131 performs filter processing (high-pass filter processing) on the output signal (input signal PI) of the detection circuit 60 to remove the DC component from the output signal. The square arithmetic processing unit 133 squares the signal after removing the DC component. The smoothing circuit 134 smoothes the signal squared by the square arithmetic processing unit 133 and obtains the root mean square. The noise component of the signal is extracted by the root mean square. The smoothing circuit 134 may be realized by, for example, a low-pass filter. From the smoothing circuit 134, the effective value (variance of floor noise) of the floor noise is output.

However, the arithmetic circuit 132 may obtain an effective value of the floor noise. The effective value is not limited to the signal level of the signal whose input signal PI is subjected to square arithmetic processing but may be another value representing the magnitude of the signal value. The magnitude of the signal value is a positive value generated based on the signal and for example, is the absolute value of the signal value, the square of the signal value, the peak-to-peak value of the signal, the difference between the maximum value and the minimum value of the signal within a predetermined time, and the like. Alternatively, the magnitude of the signal value may be a value obtained by performing some calculation (for example, gain processing or the like) thereon.

For example, the arithmetic circuit 132 may include an absolute value arithmetic processing unit and a smoothing circuit 134 that smoothes the output of the absolute value arithmetic processing unit. In this case, information corresponding to the average of the absolute values of the floor noise is output from the smoothing circuit 134.

As described above, by using the floor noise detection circuit 130, index information (variance, absolute value average, and the like) representing the level of the floor noise is obtained. The processing circuit 100 includes an abnormality detection unit 170 that compares the index value that is index information of the floor noise with the threshold value and performs abnormality detection. Here, the threshold value is a value that may distinguish between the index value of the floor noise in the normal state and the index value of the floor noise in an abnormal state. In the example in which the index value increases as the noise level of the floor noise increases, the abnormality detection unit 170 determines that an abnormality has occurred in a case where the index value represented by the index information is smaller than the threshold value.

### 2.2 Second Embodiment

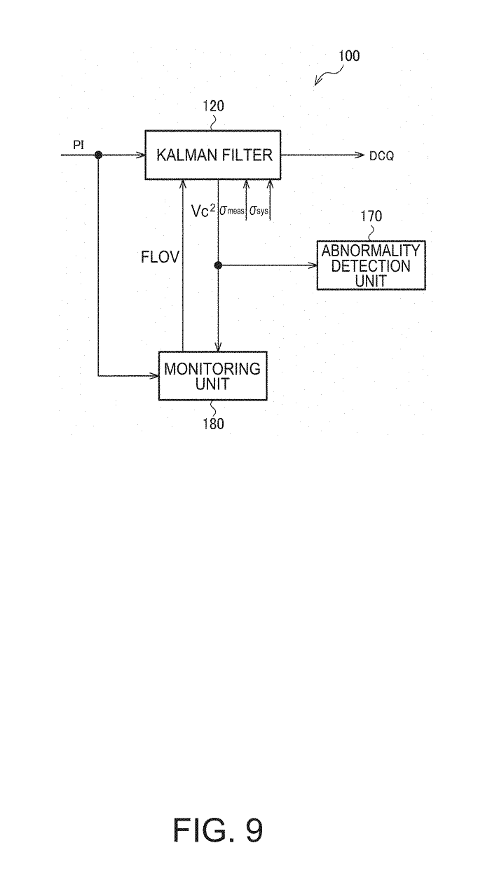

FIG. 9 shows a configuration example of the processing circuit 100 according to a second embodiment. The processing circuit 100 includes a Kalman filter 120, an abnormality detection unit 170, and a monitoring unit 180. In addition, the embodiment is not limited to the configuration of FIG. 9, and various modifications such as omitting a part of the constituent elements thereof, adding other constituent elements, and the like may be made. For example, the monitoring unit 180 may be omitted and the Kalman filter 120 having a widely-known configuration may be used.

The Kalman filter 120 performs Kalman filter processing based on observation noise σₘₑₐₛ and system noise σ_{sys} and outputs a DC component DCQ of the input signal PI as an estimation value. In addition, the Kalman filter 120 outputs error covariance Vc² of the estimation value to the abnormality detection unit 170.

By using the DC component DCQ of the input signal PI estimated by the Kalman filter 120, the DC offset (error of zero point) may be reduced. For example, the processing circuit 100 may perform processing of subtracting the estimated DC component DCQ from the input signal PI.

Here, the Kalman filtering processing is processing of estimating an optimum state of the system by using an observation value acquired from the past to the present, assuming that noise (error) is included in the observation values and a variable representing the state of the system. In the case of the embodiment, the observation value is the input signal PI, and a variable to be estimated is the DC component DCQ. In the Kalman filter processing, observation updating (observation process) and time updating (prediction process) are performed repeatedly to estimate the state. The observation updating is a process of updating a Kalman gain, an estimation value, error covariance by using the observation value and the result of the time updating. The time updating is a process of predicting the estimation value and error covariance at a next time by using the result of the observation updating.

As the observation noise σₘₑₐₛ and the system noise σ_{sys}, predetermined values estimated in advance are used, for example. In this case, the observation noise σₘₑₐₛ and the system noise σ_{sys} (or variance thereof σₘₑₐₛ² and σ_{sys}²) are stored, for example, in a register or a memory, and the Kalman filter 120 reads the observation noise σₘₑₐₛ and the system noise σ_{sys} from the register or the memory. Alternatively, the processing circuit 100 may include a noise estimation unit 110 that dynamically changes the observation noise σₘₑₐₛ and the system noise σ_{sys}, as described in the third embodiment. In this case, the observation noise σₘₑₐₛ and the system noise σ_{sys} are supplied from the noise estimation unit 110 to the Kalman filter 120.

The DC component DCQ estimated (extracted) by the Kalman filter 120 is a component whose frequency is lower than a desired signal component to be extracted from the input signal PI. For example, in a gyro sensor, the input signal PI (physical quantity signal) includes an offset, and a change based on the offset is an actual signal component. The frequency of the signal component corresponds to the frequency of the motion detected by the gyro sensor. Since the offset varies with time due to a temperature change or the like, the offset is not a frequency of zero, but a frequency lower than the frequency of the motion.

The error covariance Vc² is estimated by the Kalman filter 120 as to how much the estimation value (DC component DCQ) may be trusted. The error covariance Vc² decreases as it is determined that an estimation value close to a true value is obtained. In other words, the case where the error covariance Vc² becomes sufficiently small (converges to a predetermined value) represents a state in which the estimation accuracy of the DC component is sufficiently high. As the floor noise included in the input signal PI decreases, the estimation accuracy of the DC component also increases, and the error covariance Vc² further decreases. In other words, since the error covariance Vc² is information that becomes smaller as the floor noise decreases, the error covariance Vc² may be used as index information of the floor noise.

The abnormality detection unit 170 performs abnormality detection based on the comparison of the value of the error covariance Vc² from the Kalman filter 120 and a given threshold value. Since the error covariance Vc² is not always the value of the floor noise itself, the threshold here may be set in consideration of this point.

In JP-A-2015-114220, it is determined whether or not the signal level of the input signal exceeds a predetermined range. In a case where it is determined that the signal level of the input signal exceeds the predetermined range, the time updating of the error covariance is stopped. The Kalman filter 120 of the embodiment may have the same configuration as that of JP-A-2015-114220.

However, according to the method of JP-A-2015-114220, the threshold setting for switching between validity and invalidity of the estimation operation of the Kalman filter is fixed. Therefore, in a case where there is an input smaller than a fixed threshold (for example, rotation of a minute angular velocity in the gyro sensor), the estimation operation of the Kalman filter does not stop and there is a possibility that the estimation value follows the input. Doing so may reduce the accuracy or stability of the estimation value with respect to the true value of the DC component.

Therefore, the processing circuit 100 of the embodiment may include the monitoring unit 180 as shown in FIG. 9. The monitoring unit 180 instructs to stop the observation updating processing in the Kalman filter 120 based on the result of the determination processing based on the error covariance Vc² with respect to the signal level corresponding to the input signal PI. In this way, it is possible to adaptively change the signal level for instructing to stop observation updating processing according to the error covariance Vc². For example, it is possible to set a threshold that varies according to the error covariance Vc², not a fixed threshold.

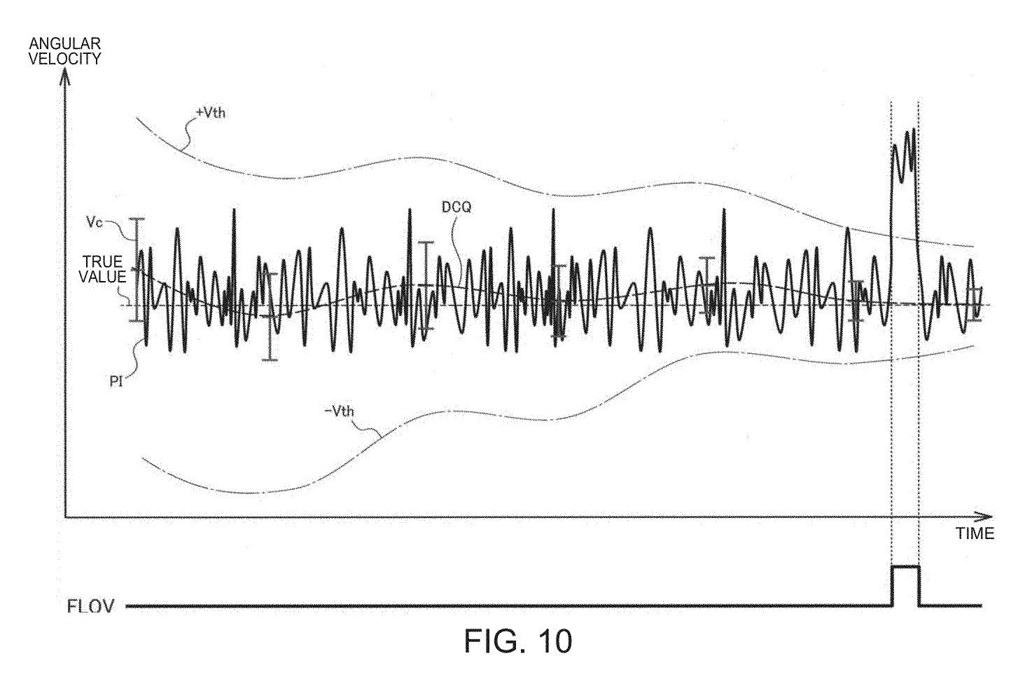

FIG. 10 is a timing chart schematically showing an operation of the signal processing apparatus of the embodiment. Noise is included in the input signal PI which is the observation value. The Kalman filter 120 estimates a true value (true zero point) from the input signal PI including this noise and outputs the estimation value as the DC component DCQ. In addition, the Kalman filter 120 estimates the likelihood of the estimation value as the error covariance Vc². In FIG. 10, an error estimation value Vc (deviation) which is the square root of the error covariance is shown. In addition, in FIG. 10, the error estimation value Vc is shown in the range, but an upper limit of this range corresponds to +Vc and a lower limit corresponds to −Vc. The Kalman filter 120 estimates that a true value exists in the distribution having the estimation value (DC component DCQ) centered and the error estimation value Vc as a deviation.

The monitoring unit 180 sets a threshold value Vth used for stop determination of the observation updating processing according to the error estimation value Vc. Specifically, as the error estimation value Vc decreases, the threshold value Vth decreases. For example, as will be described later with reference to FIG. 12, the square of the threshold value Vth² is obtained by a linear function having the error covariance Vc² as a variable. In a case where the input signal PI is out of the range of −Vth to +Vth, the monitoring unit 180 sets a stop flag FLOV from inactive (first logical level and low level) to active (second logical level and high level). FIG. 10 shows an example in which the stop flag FLOV is set to be active when the input signal PI exceeds +Vth. Setting the stop flag FLOV to be active corresponds to an instruction to stop the observation updating processing, and the Kalman filter 120 stops the observation updating processing while the stop flag FLOV is active.

### 2.3 Third Embodiment

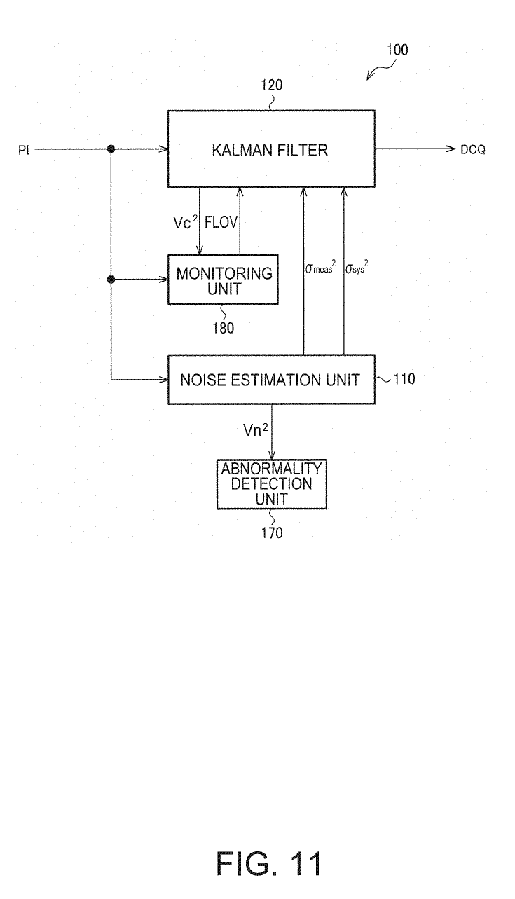

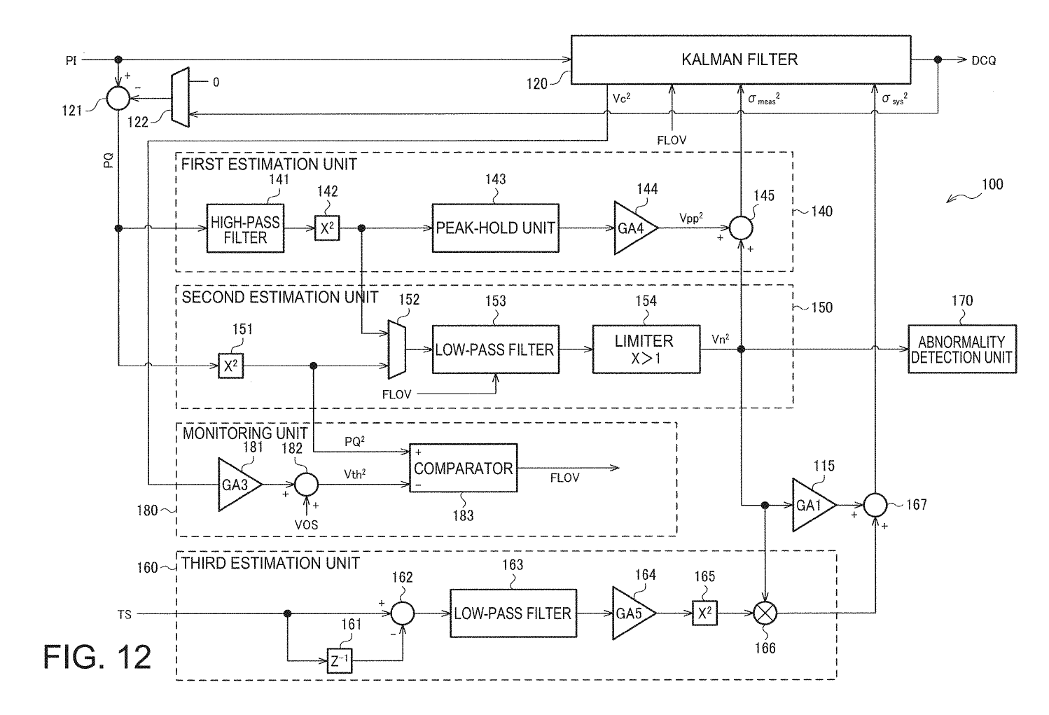

FIG. 11 shows a configuration example of the processing circuit 100 according to a third embodiment. In FIG. 11, the processing circuit 100 further includes a noise estimation unit 110 when compared with the configuration of FIG. 9. The same reference numerals are given to the constituent elements described with reference to FIG. 9, and the explanation thereof is appropriately omitted. In addition, the embodiment is not limited to the configuration of FIG. 11, and various modifications such as omitting a part of the constituent elements thereof, adding other constituent elements, and the like may be made.

The noise estimation unit 110 estimates the observation noise σₘₑₐₛ and the system noise σ_{sys} dynamically changing according to the input signal PI (input data). Specifically, the noise estimation unit 110 generates the system noise from the input signal PI and changes the variance σₘₑₐₛ² of the observation noise and the variance σ_{sys}² of the system noise according to the signal value of the input signal PI or the change thereof. The noise estimation unit 110 outputs the estimated observation noise σₘₑₐₛ and the system noise σ_{sys} to the Kalman filter 120.

The Kalman filter 120 performs Kalman filter processing based on the variance σₘₑₐₛ² of the observation noise estimated by the noise estimation unit 110 and the variance σ_{sys}² of the system noise to extract the DC component DCQ of the input signal PI.

For a general Kalman filter, an initial value of the error covariance and the system noise are given in advance as known ones. The value of the error covariance is updated by the observation updating and the time updating. As described above, for a general Kalman filter, the observation noise and the system noise are not externally given newly during the repetition of the updating.

On the other hand, in the embodiment, the observation noise σₘₑₐₛ and the system noise σ_{sys} are dynamically changed and supplied from the outside to the Kalman filter 120. As will be described in the following Equations (2) to (6), the observation noise σₘₑₐₛ and the system noise σ_{sys} affect internal variables such as a Kalman gain g(k) and the like. That is, it means that a filter characteristic of the Kalman filter 120 may be adaptively controlled by controlling the observation noise σₘₑₐₛ and the system noise σ_{sys}. In the embodiment, by using this point, when the DC component of the input signal PI (the physical quantity signal of the gyro sensor) is not changing, a passing band may be set to a low frequency and the passing band of the signal component may be extended to the low-frequency side. In addition, when the DC component changes, the observation noise σₘₑₐₛ and the system noise σ_{sys} are changed to extend the passing band so as to conform to the change in the DC component. In this way, it is possible to improve the transient responsiveness to the change of the input signal PI and the conformity with the change of the DC component.

As will be described later with reference to FIG. 12, the noise estimation unit 110 includes a second estimation unit 150 having the same configuration as the floor noise detection circuit 130 shown in FIG. 8 and estimates the observation noise σₘₑₐₛ and the system noise σ_{sys} based on an output Vn² of the second estimation unit 150. The output Vn² of the second estimation unit 150 may be used as an index value of the floor noise. That is, in the processing circuit 100 of the embodiment, the configuration for improving the transient responsiveness and conformity of the Kalman filter 120 may be used for estimating the floor noise. In other words, by the noise estimation unit 110 of the embodiment, it is possible to realize two kinds of processing of improving the characteristic of the Kalman filter 120 and calculating index information for detecting an abnormality.

The details of Kalman filter processing will be described below. The Kalman filter 120 performs first linear Kalman filter processing shown in the following Equations (2) to (6).

$$\begin{matrix}{x}^{-} ( k ) = x ( k - 1 ) & ( 2 ) \\ {P}^{-} ( k ) = P ( k - 1 ) + {{σ}_{sys} ( k - 1 )}^{2} & ( 3 ) \\ g ( k ) = \frac{{P}^{-} ( k )}{{P}^{-} ( k ) + {{σ}_{meas} ( k )}^{2}} & ( 4 ) \\ x ( k ) = {x}^{-} ( k ) + g ( k ) ( y ( k ) - {x}^{-} ( k ) ) & ( 5 ) \\ P ( k ) = ( 1 - g ( k ) ) {P}^{-} ( k ) & ( 6 )\end{matrix}$$

Equations (2) and (3) are equations of the time updating (prediction process), and the above Equations (4) to (6) are equations of the observation updating (observation process). k represents a discrete time, and time updating and observation updating are performed once each time k progresses by one. x(k) is the estimation value of the Kalman filter 120. That is, DCQ=×(k). x⁻(k) is a predictive estimate predicted before obtaining the observed value. P(k) is the error covariance of the Kalman filter 120. That is, Vc²=P(k). P⁻(k) is the error covariance predicted before the observed value is obtained. y(k) is the observed value. That is, PI=y(k). σ_{sys}(k) is the system noise, and σₘₑₐₛ (k) is the observation noise.

The Kalman filter 120 stores an estimation value x(k−1) and error covariance P(k−1) updated at a previous time k−1. Then, the observation value y(k), the observation noise σₘₑₐₛ (k), and the system noise σ_{sys}(k) are accepted at the current time k, and the time updating and observation updating of the above Equations (2) to (6) are performed by using the accepted values and an estimation value x(k) is output as a DC component.

Stopping observation updating processing is stopping the updating of at least one of the estimation value and the error covariance. Stopping updating of the estimation value is to stop updating by the above Equation (5). For example, storing the calculation result on the right side of Equation (5) in the register corresponds to updating of the estimation value. By stopping the storing in this register, updating of the estimation value is stopped. Alternatively, updating of the estimation value may be stopped by stopping the calculation on the right side of the above Equation (5). Stopping the updating of the error covariance is to stop updating by the above Equation (6).

### 2.4 Modification Example

The methods of obtaining index information of the floor noise are not limited to those described in the first to third embodiments.

For example, in the third embodiment, an example in which Vn² which is the output of the noise estimation unit 110 is used as index information (index value) of floor noise, but as in the second embodiment, the error covariance Vc² output from the Kalman filter 120 may be used as index information of the floor noise. Alternatively, the abnormality detection unit 170 may perform abnormality detection by using both of Vn² as first index information and the error covariance Vc² as second index information. Alternatively, the abnormality detection unit 170 is configured to acquire two pieces of index information, and the selected one piece of information may be used for abnormality detection.

In addition, it is also possible to combine the first embodiment and the second embodiment. For example, the processing circuit 100 may include the floor noise detection circuit 130 shown in FIG. 8 and the Kalman filter 120 (observation noise σₘₑₐₛ and system noise σ_{sys} are fixed Kalman filters) shown in FIG. 9. Then, the abnormality detection unit 170 performs abnormality detection by using a first index value from the floor noise detection circuit 130 and a second index value that is the error covariance Vc² of the Kalman filter 120.

### 3. Detailed Configuration Example of Processing Circuit

FIG. 12 is a detailed configuration example of the processing circuit 100 in the third embodiment. The processing circuit 100 includes a Kalman filter 120, a first estimation unit 140, a second estimation unit 150, a third estimation unit 160, a monitoring unit 180, an abnormality detection unit 170, a subtraction processing unit 121, a selector 122, a gain processing unit 115, and an addition processing unit 167. The first estimation unit 140, the second estimation unit 150, the third estimation unit 160, the gain processing unit 115, and the addition processing unit 167 correspond to the noise estimation unit 110 in FIG. 11. The configuration of the processing circuit 100 is not limited to FIG. 12, and various modifications such as omitting a part of the components thereof, adding other components, and the like may be made.

The selector 122 selects either the DC component DCQ estimated by the Kalman filter 120 or data “0”. The subtraction processing unit 121 subtracts the output of the selector 122 from the input signal PI and outputs the result as a signal PQ. In a case where the selector 122 selects the DC component DCQ, PQ=PI−DCQ, and in a case where the selector 122 selects data “0”, PQ=PI. The selector 122 may be omitted and the DC component DCQ may be directly input to the subtraction processing unit 121. Alternatively, the selector 122 and the subtraction processing unit 121 may be omitted, and the input signal PI may be directly used as the signal PQ.

The monitoring unit 180 includes a gain processing unit 181, an offset addition processing unit 182, and a comparator 183. The gain processing unit 181 performs gain processing on the error covariance Vc². The offset addition processing unit 182 adds an offset VOS to the output of the gain processing unit 181. The comparator 183 performs process of comparing the signal level of the signal PQ and the output of the offset addition processing unit 182 as the determination processing based on the error covariance Vc².

Specifically, the gain processing unit 181 multiplies the error covariance Vc² by a gain GA3. The output of the offset addition processing unit 182 corresponds to the square of the threshold value Vth (Vth²), and the following Equation (7) is obtained. The comparator 183 compares the square (PQ²) of the signal PQ with the square (Vth²) of the threshold Vth and outputs an active stop flag FLOV in a case where the square (PQ²) of the signal PQ is larger than the square (Vth²) of the threshold Vth, and outputs an inactive stop flag FLOV in a case where the square (PQ²) of the signal PQ is smaller than the square (Vth²) of the threshold Vth. Details of the gain GA3 and the offset VOS of the following Equation (7) will be described later.

Vth²=GA3×Vc²+VOS (7)

According to the embodiment, by performing gain processing on the error covariance Vc² and adding the offset VOS to the result, it is possible to obtain the threshold value Vth that changes according to the error covariance Vc². Then, by comparing the signal level of the signal PQ with the output of the offset addition processing unit 182, it is possible to determine whether or not the signal level has exceeded the threshold value Vth that changes according to the error covariance Vc². In addition, since the square of the threshold value Vth is obtained by a linear function (gain processing, addition processing of offset) of the error covariance Vc², the threshold value Vth may be adjusted by the linear function. Thus, it is possible to set an appropriate threshold value Vth for the system.

The first estimation unit 140 estimates the noise due to the motion of the gyro sensor (a large change in the input signal PI). Specifically, the first estimation unit 140 includes a high-pass filter 141, a square arithmetic processing unit 142, a peak-hold unit 143, a gain processing unit 144, and an addition processing unit 145.

The high-pass filter 141 removes the DC component from the signal PQ. Since the square mean is performed at a later stage, it is possible to prevent the DC component from being squared and becoming an error of the observation noise σₘₑₐₛ by eliminating the DC component. The square arithmetic processing unit 142 squares the signal from the high-pass filter 141. The peak-hold unit 143 receives the signal of an AC component passed through the high-pass filter 141 and the square arithmetic processing unit 142 and holds the peak of the signal. The gain processing unit 144 performs gain processing (processing of multiplying by a gain GA4) on the output of the peak-hold unit 143 and outputs the result as motion noise Vpp² (variance of the motion noise). The addition processing unit 145 adds the motion noise Vpp² and the floor noise Vn² generated by the second estimation unit 150 and outputs the result as the variance σₘₑₐₛ² of the observation noise.

As the motion detected by the gyro sensor is larger, the signal from the peak-hold unit 143 also becomes larger, so the observation noise σₘₑₐₛ increases as the motion increases. Increasing observation noise σₘₑₐₛ decreases the Kalman gain g(k) as seen from the above Equation (4), and as can be seen from the above Equation (5), the weight of the observation value y(k) is lowered and the estimation value x(k) can be calculated. As a result, as the AC component of the motion increases, the influence of the observed value y(k) decreases, and DC components with higher accuracy may be extracted.

The floor noise output from the motion noise Vpp² is expressed by the following Equation (8). Vn is the floor noise of the input signal PI. GA4 is a gain of the gain processing unit and is a coefficient for adjusting the degree of influence of the peak-hold unit 143. Peak-hold processing of the squared signal of noise results in outputting a maximum value during a certain period of time, and an effective gain Gₚₑₐₖ is applied to the average value of the squared signal of the noise. The peak-hold unit 143 holds the peak of the input signal and then outputs a signal divided by Gₚₑₐₖ.

Vpp²=GA4×Vn² (8)

The second estimation unit 150 estimates the floor noise of the input signal PI. Specifically, the second estimation unit 150 includes a square arithmetic processing unit 151, a selector 152, a low-pass filter 153, and a limiter 154.

The square arithmetic processing unit 151 squares the signal PQ. The selector 152 selects the output of the square arithmetic processing unit 151 or the output of the square arithmetic processing unit 142 of the first estimation unit 140. The low-pass filter 153 filters (smoothes) the signal squared by the square arithmetic processing unit 151 and obtains the root mean square thereof. The noise component of the signal is extracted by the root mean square. The limiter 154 performs limit processing on the signal from the low-pass filter 153. Specifically, in a case where the signal from the low-pass filter 153 is equal to or lower than a lower limit value, the output is limited to the lower limit value, and in a case where the signal from the low-pass filter 153 is larger than the lower limit value, the signal is output as it is. The lower limit value is smaller than an assumed minimum floor noise and is, for example, 1 digit. As a result, from the output of the limiter 154, the index value Vn² of the floor noise (index value corresponding to the variance of the floor noise) is output.

The gain processing unit 115 multiplies the floor noise Vn² from the second estimation unit 150 by a constant gain GA1 and outputs the result to the addition processing unit 167. The gain GA1 is set as shown in the following Equation (12). The derivation method of the following Equation (12) will be described below.

First, a relationship between the observation noise σₘₑₐₛ and the system noise σ_{sys} in a state where sufficient time has elapsed is obtained. The state in which sufficient time has elapsed may be set by assuming a situation where k=cc, and if prior error covariance P⁻(k) converges to a fixed value, the following Equation (9) holds. The convergence value of the prior error covariance P⁻(k) is P₀.

P₀=P⁻(k)=P⁻(k+1) (9)

The following Equation (10) is obtained by solving the Kalman gain g(k) with simultaneous equations of the above Equations (3) and (6) applied with the above Equation (9) and the above Equation (4) applied with the above Equation (9). In the following Equation (10), the Kalman gain g(k) at the convergence state k=∞ is set to g. In addition, in the approximation on the right side, it is assumed that σ_{sys}<<σₘₑₐₛ holds because the passing band is very low in the convergence state of the Kalman filter 120.

$$g = g ( k = ∞ ) ≅ \frac{{σ}_{sys}}{{σ}_{meas}} \qquad ( 10 )$$

From the above Equation (10), since σ_{sys}²=g²σₘₑₐₛ² in the convergence state, the gain GA1=g². If the relationship between a desired filter characteristic for extracting the DC component and the Kalman gain g is known, the gain GA1 may be set so as to obtain the desired filter characteristic.

The following Equation (11) is obtained by obtaining a final transfer function when time has elapsed from the above Equations (2) and (5), applying bilinear transformation to the transfer function, obtaining a cutoff frequency f_{c} of the low-pass filter characteristic included in the transfer function, and solving for the Kalman gain g. fₛ is a sampling frequency (operating frequency) of the Kalman filter 120. In the approximation on the right side of the following Equation (11), f_{c}<<fₛ is set.

$$g = \frac{{σ}_{sys}}{{σ}_{meas}} ≅ \frac{2 π {f}_{c}}{{f}_{s}} \qquad ( 11 )$$

From the above Equation (11), the gain GA1=g² may be obtained by the following Equation (12). In the following Equation (12), a desired cutoff frequency (target cutoff frequency) to be finally obtained in the convergence state is set to f_{c}.

$$GA 1 = {( \frac{2 π {f}_{c}}{{f}_{s}} )}^{2} \qquad ( 12 )$$

The third estimation unit 160 estimates the variation of the zero point (DC offset) due to the temperature fluctuation. The third estimation unit 160 increases the system noise σ_{sys} in a case where there is a temperature change and returns the Kalman filter 120 from the converging state to an estimation state. Specifically, the third estimation unit 160 includes a delay unit 161, a subtraction processing unit 162, a low-pass filter 163, a gain processing unit 164, a square arithmetic processing unit 165, a multiplication processing unit 166, and an addition processing unit 167.

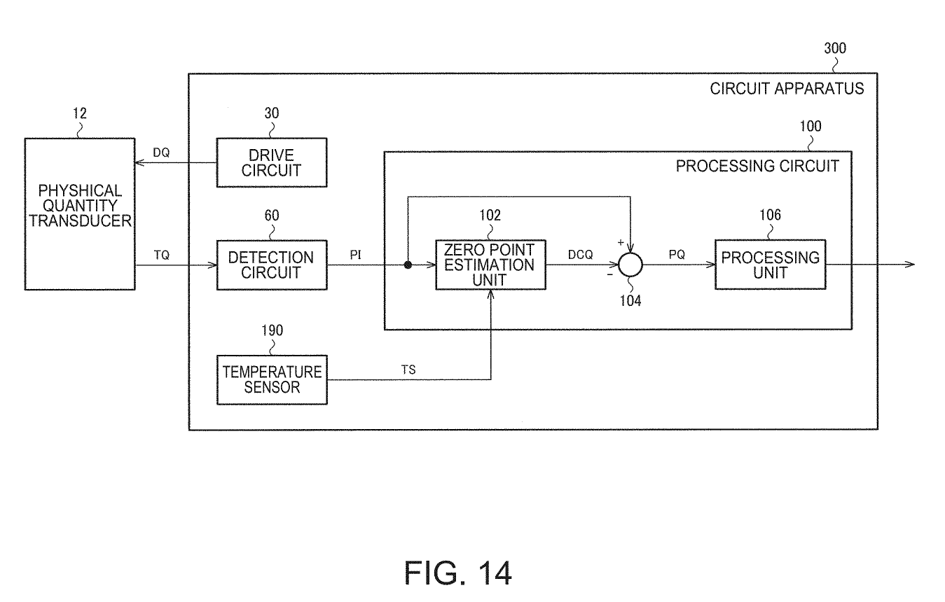

The delay unit 161 and the subtraction processing unit 162 obtain a difference between a detection signal TS at a time k of a temperature sensor (for example, a temperature sensor 190 in FIG. 14) and the detection signal TS at the previous time k−1. The low-pass filter 163 smoothes the difference.

The gain processing unit 164 multiplies the signal from the low-pass filter 163 by a gain GA5. The square arithmetic processing unit 165 squares the multiplied signal. The multiplication processing unit 166 multiplies the signal after the squaring by the index value Vn² of the floor noise from the second estimation unit 150. The addition processing unit 167 adds the output of the multiplication processing unit 166 and the output of the gain processing unit 115 and outputs the result as the variance σ_{sys}² of the system noise to the Kalman filter 120.

The gain GA 5 is set by the following Equation (13). TSEN is sensitivity (digi/° C.) of the temperature sensor, TCOEFF is a temperature coefficient of the gyro sensor (dps/° C.), and SEN is sensitivity (digit/dps) of the gyro sensor.

$$GA 5 = \frac{SEN \times TCOEFF}{TSEN} \qquad ( 13 )$$

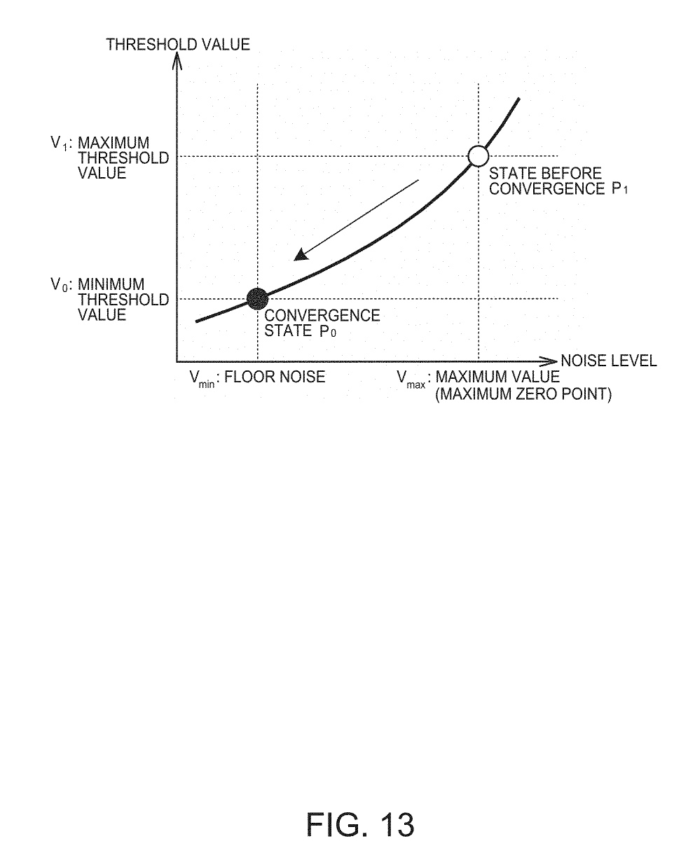

Hereinafter, with reference to FIG. 13, the gain GA3 and the offset VOS of Expression (7) above in which the monitoring unit 180 sets the threshold value Vth will be described. FIG. 13 is a diagram for explaining a setting method of the threshold value Vth.

The variance σₘₑₐₛ² of the observation noise is obtained by the following Equation (14) from the above Equation (8).

σₘₑₐₛ²=Vpp²+Vn²=(1+GA4)×Vn² (14)

If it is assumed that the noise level of the input signal PI in the convergence state of the error covariance state is Vₘᵢₙ (floor noise), Vn²=Vₘᵢₙ². At this time, the following Expression (15) holds from the above Expression (14). In addition, at the start of the operation (before convergence), the signal PQ is the DC component DCQ of the input signal PI. If it is assumed that a possible maximum value of the DC component DCQ is Vₘₐₓ (maximum zero point error), the output of the high-pass filter 141 is Vₘₐₓ, the output of the square arithmetic processing unit 142 is Vₘₐₓ², and the output of the gain processing unit 144 is GA4×Vₘₐₓ². On the other hand, the output of the low-pass filter 153 becomes Vₘₐₓ², and the following Equation (16) holds. In order to simplify the calculation, the effective gain Gₚₑₐₖ of the peak-hold unit 143 is set to 1.

σₘₑₐₛ²=(1+GA4)×Vₘᵢₙ² (15)

σₘₑₐₛ²=(1+GA4)×Vₘₐₓ² (16)

In the convergence state, the following Equation (17) holds from the above Equations (3), (6), and (10).

$$P ( k ) = ( 1 - g ( k ) ) ( P ( k - 1 ) + {σ}_{sys}^{2} ) ∼ \frac{1}{1 + \frac{{σ}_{sys}}{{σ}_{meas}}} ( P ( k - 1 ) + {σ}_{sys}^{2} ) \qquad ( 17 )$$

From the above Equations (9), (11), and (17), the following Equation (18) is obtained as the error covariance P₀ in the convergence state.

$${P}_{0} = \frac{2 π {f}_{c}}{{f}_{s}} {σ}_{meas}^{2} \qquad ( 18 )$$

If it is assumed that the state before the convergence is a state before a time constant time of a target cutoff frequency f_{c}, the following Equation (19) is obtained as the error covariance P₁ in the state before convergence.

$${P}_{1} = β \times {P}_{0} , β = {( \frac{2 π {f}_{c}}{{f}_{s}} )}^{\frac{fs}{fc}} \qquad ( 19 )$$

As shown in FIG. 13, the threshold value in the state before convergence is set as a maximum threshold value V₁, and the threshold value in the convergence state is set as a minimum threshold value V₀. From the above Equation (7), the maximum threshold value V₁ may be set as the following Equation (20) and the minimum threshold value V₀ may be set as the following Equation (21).

V₁²=P₁×GA3+VOS (20)

V₀²=P₀×GA3+VOS (21)

By solving the above Equations (20) and (21) as simultaneous Equations and using the above Equations (15), (16), (18), and (19), the following Equations (22) and (23) are obtained. That is, the gain GA3 of the monitoring unit 180 is set by the following Equation (22), and the offset VOS is set by the following Equation (23).

$$\begin{matrix}GA 3 = \frac{{f}_{s}}{2 π {f}_{c} ( 1 + GA 4 )} \times \frac{{V}_{1}^{2} - {V}_{0}^{2}}{β {V}_{max}^{2} - {V}_{min}^{2}} & ( 22 ) \\ VOS = \frac{β {V}_{max}^{2} {V}_{0}^{2} - {V}_{min}^{2} {V}_{1}^{2}}{β {V}_{max}^{2} - {V}_{min}^{2}} & ( 23 )\end{matrix}$$

### 4. Circuit Apparatus and Physical Quantity Measuring Apparatus

FIG. 14 is a detailed configuration example of the circuit apparatus 300 (detection apparatus) of the embodiment. The circuit apparatus 300 includes a drive circuit 30, a detection circuit 60, a processing circuit 100 (signal processing circuit), and a temperature sensor 190. The circuit apparatus 300 is not limited to the configuration of FIG. 14, and various modifications such as omitting a part (for example, a temperature sensor) of the constituent elements thereof, adding other constituent elements, and the like may be made.

The drive circuit 30 supplies a drive signal DQ to the physical quantity transducer 12 to drive the physical quantity transducer 12. The detection circuit 60 receives the detection signal TQ from the physical quantity transducer 12 and detects a physical quantity signal corresponding to the physical quantity. The processing circuit 100 (abnormality detection unit 170) performs an abnormality detection of the physical quantity measuring apparatus using the physical quantity signal as the input signal PI.

Specifically, the physical quantity transducer 12 is an element or a device for detecting a physical quantity. The physical quantity is, for example, angular velocity, angular acceleration, velocity, acceleration, distance, pressure, sound pressure, magnetic quantity or time. The circuit apparatus 300 may detect the physical quantity based on detection signals from a plurality of physical quantity transducers. For example, first to third physical quantity transducers detect the physical quantity of a first axis, a second axis, and a third axis, respectively. The physical quantities of the first axis, the second axis, and the third axis are, for example, angular velocity or angular acceleration about the first axis, the second axis, the third axis, or velocity or acceleration, and the like in the directions of the first axis, the second axis, and the third axis. The first axis, the second axis, and the third axis are, for example, an X-axis, a Y-axis, and a Z-axis. The physical quantities of only two axes out of the first to third axes may be detected.

The processing circuit 100 is realized by a processor such as a DSP (Digital Signal Processor), and the processing of each unit is realized by time division processing by DSP, for example. Alternatively, each unit of the processing circuit 100 may be configured as individual hardware (logic circuit).

The zero point estimation unit 102 dynamically changes the observation noise and the system noise based on the input signal PI and the detection signal TS (temperature detection voltage) from the temperature sensor 190 and performs Kalman filter processing based on the observation noise and system noise to estimate the DC component DCQ (DC offset and zero point) of the input signal PI. The zero point estimation unit 102 corresponds to the Kalman filter 120 and the monitoring unit 180 in FIG. 9 or the Kalman filter 120, the monitoring unit 180, and the noise estimation unit 110 in FIG. 11.

The subtraction processing unit 104 subtracts the DC component DCQ from the input signal PI and outputs the result as the signal PQ. The subtraction processing unit 121 of FIG. 12 may be used as the subtraction processing unit 104.

The processing unit 106 performs various digital signal processing (for example, correction, integration, and the like) on the signal PQ and outputs a digital value representing a physical quantity. The type of the physical quantity output by the processing unit 106 may be the same as or different from the type of the physical quantity detected by the detection circuit 60. For example, in the gyro sensor, the detection circuit 60 detects the angular velocity, but the processing unit 106 may output the angular velocity or may output the angle obtained by integrating the angular velocity.

FIG. 15 is a configuration example of a physical quantity measuring apparatus including the circuit apparatus of the embodiment. FIG. 15 shows a configuration example of a gyro sensor that detects angular velocity as an example of the physical quantity measuring apparatus. The processing circuit 100 of the embodiment may be applied to a physical quantity measuring apparatus that detects various physical quantities such as angular velocity, angular acceleration, velocity, acceleration, distance, pressure, sound pressure, magnetic amount, time, and the like.

The gyro sensor 400 (angular velocity sensor) includes a vibrator 10, a drive circuit 30, a detection circuit 60, and a processing circuit 100.

The vibrator 10 (angular velocity detection element) is a device (physical quantity transducer) that detects a Coriolis force acting on the vibrator 10 by rotation on a predetermined axis and outputs a signal corresponding to the Coriolis force. The vibrator 10 is, for example, a piezoelectric vibrator. For example, the vibrator 10 is a double T-shaped, T-shaped, tuning-fork-type crystal vibrator, and the like. As the vibrator 10, a MEMS (Micro Electro Mechanical Systems) vibrator or the like as a silicon vibrator formed by using a silicon substrate or the like may be adopted.

The drive circuit 30 includes an amplifier circuit 32 to which a feedback signal DI from the vibrator 10 is input, a gain control circuit 40 that performs automatic gain control, and a drive signal output circuit 50 that outputs the drive signal DQ to the vibrator 10. In addition, the drive circuit 30 includes a synchronization signal output circuit 52 that outputs a synchronization signal SYC to the detection circuit 60.

The amplifier circuit 32 (I/V conversion circuit) amplifies the feedback signal DI from the vibrator 10. For example, the amplifier circuit 32 converts the signal DI of the current from the vibrator 10 into a voltage signal DV and outputs the result. This amplifier circuit 32 may be realized by an operational amplifier, a feedback resistance element, a feedback capacitor, or the like.

The drive signal output circuit 50 outputs the drive signal DQ based on the signal DV after amplification by the amplifier circuit 32. For example, in a case where the drive signal output circuit 50 outputs a rectangular wave (or sine wave) drive signal, the drive signal output circuit 50 may be realized by a comparator or the like.

The gain control circuit 40 (AGC) outputs a control voltage DS to the drive signal output circuit 50 to control the amplitude of the drive signal DQ. Specifically, the gain control circuit 40 monitors the signal DV and controls the gain of an oscillation loop. For example, in the drive circuit 30, in order to keep the sensitivity of the gyro sensor constant, it is necessary to keep the amplitude of the driving voltage supplied to a vibrating unit for driving the vibrator 10 constant. Therefore, the gain control circuit 40 for automatically adjusting the gain is provided in the oscillation loop of a drive oscillation system. The gain control circuit 40 automatically adjusts the gain variably so that the amplitude (vibration speed of the vibrating unit for driving the vibrator 10) of the feedback signal DI from the vibrator 10 becomes constant. This gain control circuit 40 may be realized by a full-wave rectifier that performs full-wave rectification of the output signal DV of the amplifier circuit 32, an integrator that performs integration processing of the output signal of the full-wave rectifier, or the like.

The synchronization signal output circuit 52 receives the signal DV after amplification by the amplifier circuit 32 and outputs the synchronization signal SYC (reference signal) to the detection circuit 60. The synchronization signal output circuit 52 includes a comparator that performs binarization processing of a sine wave (alternating current) signal DV to generate a rectangular wave synchronization signal SYC, a phase adjusting circuit (phase shifter) that adjusts the phase of the synchronization signal SYC, and the like.

The detection circuit 60 includes an amplifier circuit 64, a synchronous detection circuit 81, an A/D conversion circuit 82, and a processing circuit 100 (DSP). The amplifier circuit 64 receives first and second detection signals IQ1 and IQ2 from the vibrator 10 and performs charge-voltage conversion, differential signal amplification, gain adjustment, or the like. The synchronous detection circuit 81 performs synchronous detection based on the synchronization signal SYC from the drive circuit 30. The A/D conversion circuit 82 performs A/D conversion of the signal of the synchronous detection. The processing circuit 100 performs digital filter processing or digital correction processing (for example, zero point correction processing, sensitivity correction processing, or the like) on the digital signal (input signal PI) from the A/D conversion circuit 82.

### 5. Vehicle and Electronic Device

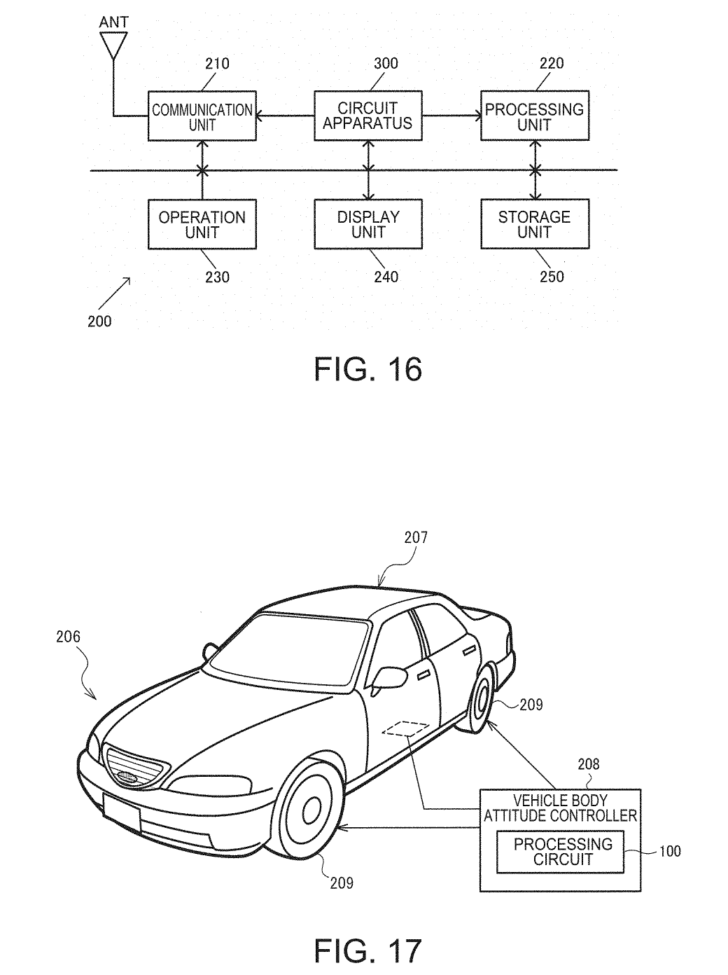

FIG. 16 shows a configuration example of an electronic device 200 of the embodiment. The electronic device 200 includes the circuit apparatus 300 of this embodiment. In addition, the electronic device 200 may include an antenna ANT, a communication unit 210, a processing unit 220, an operation unit 230, a display unit 240, and a storage unit 250. In addition, the electronic device 200 of the embodiment is not limited to the configuration of FIG. 16, and various modifications such as omitting a part of the constituent elements thereof and adding other constituent elements may be made.

As the electronic device 200 of the embodiment, various devices such as a digital camera (digital still camera or video camera), a biological information detection apparatus (pulse rate meter, activity meter, pedometer, health clock, and the like), a head mounted type display device, a robot, a GPS internal clock, a car navigation device, a game device, various wearable devices, a portable information terminal (a smartphone, a mobile phone, a portable game device, a tablet PC, and the like), a content-providing terminal, video equipment, audio equipment, or network-related equipment (base station, router, and the like) may be assumed. For example, in a digital camera, by using the circuit apparatus of the embodiment, camera shake correction using a gyro sensor, an acceleration sensor or the like may be realized. In addition, in a biological information detection apparatus, by using the circuit apparatus of the embodiment, it is possible to detect the biological motion of a user or the motion state by using the gyro sensor or the acceleration sensor. The circuit apparatus of the embodiment may be used for movable parts (arm and joint) or the main body part of a robot. In the robot, either a vehicle (running/walking robot) or an electronic device (non-running/non-walking robot) may be assumed. In the case of a running/walking robot, for example, the circuit apparatus of the embodiment may be used for autonomous traveling. In the network-related equipment, the circuit apparatus of the embodiment may be used as an apparatus for measuring time (absolute time and the like) or timing, for example.

In FIG. 16, the communication unit 210 (wireless circuit) receives data from the outside via the antenna ANT or performs processing for transmitting data to the outside. The processing unit 220 (processor) realized by a CPU, an MPU, and the like performs various arithmetic processing or control processing of the electronic device 200, based on the information stored in the storage unit 250 (memory). The operation unit 230 is a unit for the user to perform an input operation and may be realized by an operation button, a touch panel display, or the like. The display unit 240 displays various kinds of information and may be realized by a display such as liquid crystal, organic EL, or the like. The storage unit 250 stores various kinds of information, and the functions thereof may be realized by a semiconductor memory such as a RAM, ROM, an HDD (hard disk drive), or the like.

In addition, the circuit apparatus of the embodiment may be incorporated into various vehicles such as a car, an airplane, a motorbike, a bicycle, ship or the like, for example. A vehicle is a device/apparatus that moves on the ground, the sky or the sea including a driving mechanism such as an engine, a motor, or the like, a steering mechanism such as a steering wheel, a rudder, or the like, and various electronic devices.

FIG. 17 schematically shows an automobile 206 as an example of a vehicle. A gyro sensor (not shown) including the processing circuit 100 is incorporated in the automobile 206. The gyro sensor may detect the attitude of a vehicle body 207. The detection signal of the gyro sensor is supplied to a vehicle body attitude controller 208. The vehicle body attitude controller 208 may control the hardness of the suspension or control the brakes of the individual wheels 209, for example, according to the attitude of the vehicle body 207. In addition, such attitude control may be used in various vehicles such as a bipedal walking robot, an aircraft, a helicopter, and the like. A gyro sensor may be incorporated in realizing attitude control.

Although the embodiment has been described in detail as above, those skilled in the art will easily understand that many modifications may be made without deviating practically from the new matters and effects of the invention. Therefore, all such modifications are included in the scope of the invention. For example, in the specification or the drawings, terms described with broader or equivalent different terms at least once may be replaced with different terms at any point in the description or drawings. In addition, all combinations of the embodiment and modifications are included in the scope of the invention. In addition, the configurations and operations of the signal processing apparatus, the detection device, the physical quantity measuring apparatus, the electronic device, the vehicle, and the like are not limited to those described in the embodiment, and various modifications may be made.

The entire disclosure of Japanese Patent Application No. 2017-107468, filed May 31, 2017 is expressly incorporated by reference herein.

What is claimed is:

1. A circuit apparatus used in a physical quantity measuring apparatus, comprising:
a detection circuit that performs physical quantity detection processing based on a detection signal from a physical quantity transducer; and
a processing circuit that performs processing based on an output signal of the detection circuit,
wherein the processing circuit obtains index information of a floor noise generated in the detection circuit based on the output signal and performs abnormality detection of the physical quantity measuring apparatus based on the index information.

2. The circuit apparatus according to claim 1,
wherein the processing circuit performs the abnormality detection of the connection between the physical quantity transducer and the detection circuit based on the index information.

3. The circuit apparatus according to claim 1,
wherein the processing circuit includes an abnormality detection unit that compares an index value that is the index information of the floor noise with a threshold value and performs the abnormality detection.

4. The circuit apparatus according to claim 1,
wherein the detection circuit includes an amplifier circuit to which the detection signal is input, and
the floor noise includes a floor noise generated in the amplifier circuit.

5. The circuit apparatus according to claim 4,
wherein the amplifier circuit is a Q/V conversion circuit or an I/V conversion circuit.

6. The circuit apparatus according to claim 1,
wherein the processing circuit includes a floor noise detection circuit that detects the index information of a floor noise, and
the floor noise detection circuit includes an arithmetic circuit that obtains an effective value of the floor noise.

7. The circuit apparatus according to claim 6,
wherein the floor noise detection circuit includes a high-pass filter that performs filter processing on the output signal of the detection circuit, and the arithmetic circuit, the arithmetic circuit includes
a square arithmetic processing unit that performs a square operation on the filtered signal or an absolute value arithmetic processing unit that performs absolute value operation on the filtered signal, and
a smoothing circuit that smoothes the output of the square arithmetic processing unit or the absolute value arithmetic processing unit.

8. The circuit apparatus according to claim 1,
wherein the processing circuit includes the Kalman filter for performing Kalman filter processing based on observation noise and system noise to extract a DC component of the output signal of the detection circuit, and
the index information of the floor noise is error covariance output from the Kalman filter.

9. The circuit apparatus according to claim 1,
wherein the processing circuit includes
the Kalman filter for performing Kalman filter processing based on observation noise and system noise to extract a DC component of the output signal of the detection circuit and
a noise estimation unit that obtains the index information based on the output signal of the detection circuit, and
the noise estimation unit estimates the observation noise and the system noise based on the index information and outputs the observation noise and the system noise to the Kalman filter.

10. A physical quantity measuring apparatus comprising:
a physical quantity transducer;
a detection circuit that performs physical quantity detection processing based on a detection signal from the physical quantity transducer; and
a processing circuit that performs processing based on an output signal of the detection circuit,
wherein the processing circuit obtains index information of a floor noise generated in the detection circuit based on the output signal and performs abnormality detection of the physical quantity measuring apparatus based on the index information.

11. The physical quantity measuring apparatus according to claim 10,
wherein the processing circuit performs the abnormality detection of the connection between the physical quantity transducer and the detection circuit based on the index information.

12. The physical quantity measuring apparatus according to claim 10,
wherein the processing circuit includes an abnormality detection unit that compares an index value that is the index information of the floor noise with a threshold value and performs the abnormality detection.

13. The physical quantity measuring apparatus according to claim 10,
wherein the detection circuit includes an amplifier circuit to which the detection signal is input, and
the floor noise includes a floor noise generated in the amplifier circuit.

14. An electronic device comprising:
the circuit apparatus according to claim 1; and
an operation unit.

15. An electronic device comprising:
the circuit apparatus according to claim 2; and
an operation unit.

16. An electronic device comprising:
the circuit apparatus according to claim 3; and
an operation unit.

17. An electronic device comprising:
the circuit apparatus according to claim 4; and
an operation unit.

18. A vehicle comprising:
the circuit apparatus according to claim 1; and
a vehicle body.

19. A vehicle comprising:
the circuit apparatus according to claim 2; and
a vehicle body.

20. A vehicle comprising:
the circuit apparatus according to claim 3; and
a vehicle body.
